(19) United States
(12) Patent Application Publication
(10) Pub. No.: US 2025/0089285 A1
(43) Pub. Date: Mar. 13, 2025

(54) SEMICONDUCTOR DEVICE AND MANUFACTURING METHOD FOR THE SAME

(71) Applicant: Taiwan Semiconductor Manufacturing Company LTD, Hsinchu (TW)

(72) Inventors: Po-Yang Hsu, Hsinchu (TW); Lung Chen, Zhubei (TW); Long-Jie Hong, Hsinchu (TW)

(21) Appl. No.: 18/367,129

(22) Filed: Sep. 12, 2023

(51) Int. Cl. H01L 29/66; H01L 21/8234; H01L 27/088; H01L 29/78

(52) U.S. Cl. CPC H10D 30/024; H10D 30/6211; H10D 84/0158; H10D 84/038; H10D 84/834

(57) ABSTRACT

An integrated circuit includes a first fin, a second fin, and a hybrid fin located between the first fin and the second fin. The hybrid fin is shaped to include a base and a horn extending from the base on a side proximal to the second fin. An n-type epitaxial structure is supported by the first fin, and a p-type epitaxial structure is supported by the second fin. A gap fill or etch stop material is located between the hybrid fin and the second fin of the p-type epitaxial structure. The structure creates additional space to increase the size of the n-type epitaxial structure, improving device performance, and also reduces or eliminates leakage paths that can occur when the location of a metal contact is undesirably shifted.

### BACKGROUND

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-axis cross-sectional view showing a first example embodiment of a semiconductor device, in accordance with some embodiments. In this embodiment, there is one n-type epitaxial structure located between two p-type epitaxial structures.

FIG. 1B is a magnified view of a portion of the semiconductor device.

FIG. 1C is an X-axis cross-sectional view of the first example embodiment, through line C-C of FIG. 1A.

FIG. 2A is a Y-axis cross-sectional view showing a second example embodiment of a semiconductor device, in accordance with some embodiments. In this embodiment, there are two n-type epitaxial structures located between two p-type epitaxial structures.

FIG. 2B is a Y-axis cross-sectional view showing a third example embodiment of a semiconductor device, in accordance with some embodiments. In this embodiment, a single n-type epitaxial structure and a single p-type epitaxial structure are each grown upon two adjacent fins.

FIG. 3 is a flow chart illustrating a method for forming the semiconductor device, in accordance with some embodiments. Various steps of this method are shown in FIGS. 4-17.

FIG. 4 is a Y-axis cross-sectional view after a processing step.

FIG. 5 is a Y-axis cross-sectional view after a processing step.

FIG. 6 is a Y-axis cross-sectional view after a processing step.

FIG. 7 is a Y-axis cross-sectional view after a processing step.

FIG. 8 is a Y-axis cross-sectional view after a processing step.

FIG. 9 is a Y-axis cross-sectional view after a processing step.

FIG. 10 is a Y-axis cross-sectional view after a processing step.

FIG. 11 is a Y-axis cross-sectional view after a processing step.

FIG. 12 is a Y-axis cross-sectional view after a processing step.

FIG. 13 is a Y-axis cross-sectional view after a processing step.

FIG. 14 is a Y-axis cross-sectional view after a processing step.

FIG. 15 is a Y-axis cross-sectional view after a processing step.

FIG. 16 is a Y-axis cross-sectional view after a processing step.

FIG. 17 is a Y-axis cross-sectional view after a processing step.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them.

The present disclosure relates to various methods and structures which are useful in improving device performance and reducing capacitance.

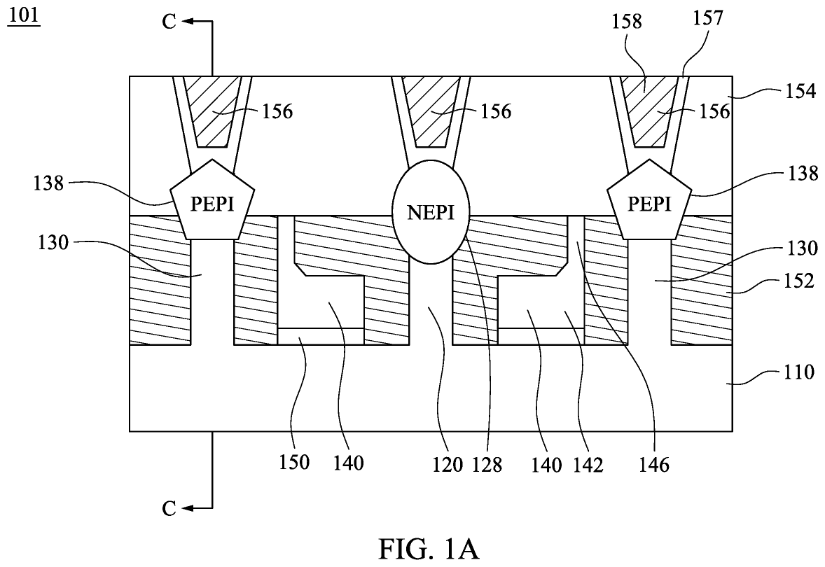

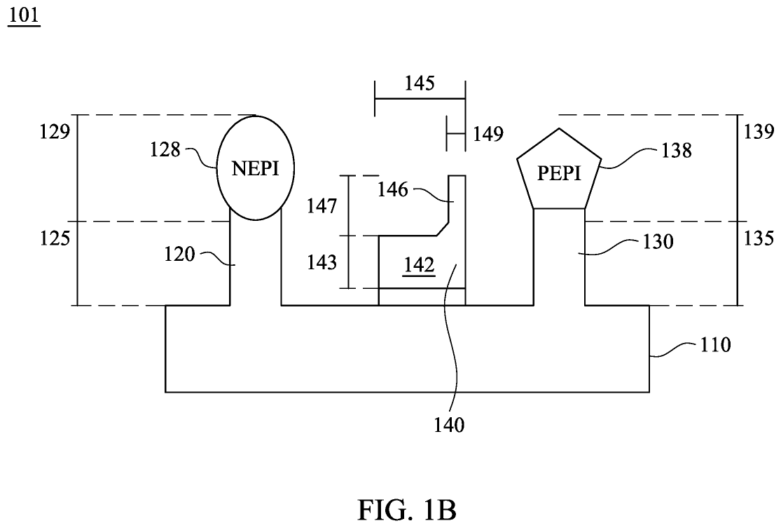

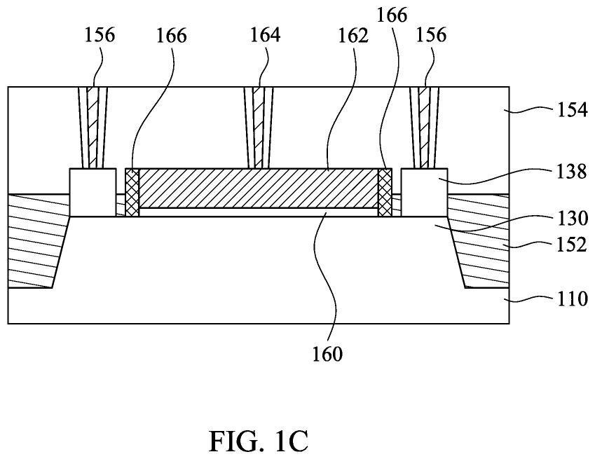

FIG. 1A is a Y-axis cross-sectional view showing a first example embodiment of a semiconductor device 101, in accordance with some embodiments of the present disclosure, and illustrating some features. FIG. 1B is a magnified view of a portion of the semiconductor device, showing additional features. FIG. 1C is an X-axis cross-sectional view of the first example embodiment, through line C-C of FIG. 1A.

Referring first to FIG. 1A, the structure includes a substrate 110 having fins rising upwards from the surface of the substrate. Commonly, the fins are made of the same material as the substrate. Three fins are illustrated here, a first fin 120 or central fin, and two second fins 130 or outer fins. Each first fin 120 supports an n-type epitaxial structure 128, and each second fin 130 supports a p-type epitaxial structure 138. These fins 120, 130 are made of a semiconducting material.

A hybrid fin 140 is located between each n-type epitaxial structure 120 and p-type epitaxial structure 130. The hybrid fin 140 sits upon a dielectric layer 150. The hybrid fin 140 itself is made of a dielectric material and acts as an insulator to reduce or eliminate junction leakage between the n-type epitaxial structure 120 and p-type epitaxial structure 130. The dielectric material that makes up the hybrid fin 140 usually has a dielectric constant greater than that of the dielectric layer 150. In particular embodiments, the dielectric layer 150 is made of silicon dioxide (SiO₂), which has a dielectric constant of 3.9.

Each hybrid fin 140 includes a base 142 and a horn 146 extending upwards from the base 142 on the side of the base proximal to the second fin 130 or p-type epitaxial structure 138. A gap fill layer or etch stop layer 152 is present between the hybrid fin 140 and the second fin 130 or p-type epitaxial structure 138. The gap fill layer or etch stop layer 152 can also be present between the hybrid fin 140 and the first fin 120 or n-type epitaxial structure 128, and is illustrated in this manner, but this is not required.

Continuing, a capping dielectric layer 154 is applied over the hybrid fins 140, the n-type epitaxial structure 128, and the p-type epitaxial structures 138. This capping layer may also be known as a pre-metal dielectric (PMD) layer. Metal contacts 156 pass through the capping dielectric layer 154 and extend down to each of the n-type epitaxial structure 128 and the p-type epitaxial structures 138. Each metal contact includes an electrical contact resistance reduction layer 157 and an electrically conductive metal plug 158. The contact resistance reduction layer 157 is located between the epitaxial structure 128, 138 and the metal plug 158, and functions to reduce the electrical contact resistance.

Referring now to FIG. 1B, the gap fill layer or etch stop layer 152 and the capping dielectric layer 154 are removed to show additional aspects of the structure. The first fin 120 has a height 125 which is measured to the base of the n-type epitaxial structure 128. The n-epitaxial structure 128 itself has a height 129. Similarly, the second fin 130 has a height 135 which is measured to the base of the p-epitaxial structure 138. The p-type epitaxial structure 138 itself has a height 139. In some embodiments, the volume of the n-type epitaxial structure is greater than the volume of the p-type epitaxial structure.

The base 142 of the hybrid fin 140 has a height 143 and a width 145. The horn 146 of the hybrid fin also has a height 147 and a width 149. The width 149 of the horn is less than the width 145 of the base. In particular embodiments, the height 143 of the base 142 is from about 20 nanometers to about 30 nanometers. In particular embodiments, the width 145 of the base 142 is from about 10 nanometers to about 20 nanometers. In particular embodiments, the height 147 of the horn 146 is from about 5 nanometers to about 10 nanometers. In particular embodiments, the width 149 of the horn 146 is from about 3 nanometers to about 8 nanometers. However, other values and ranges for these heights and widths are also within the scope of this disclosure.

The ratio of horn height 147 to base height 143 is usually from about 1:3 to about 1:1, or put another way the horn height 147 is about 25% to about 50% of the base height 143. The ratio of horn width 149 to base width 145 is usually from about 1:3 to about 1:1, or put another way the horn width 149 is about 25% to about 50% of the base width 145. Other values and ranges for these ratios are also within the scope of this disclosure.

In some particular embodiments, the height 143 of the base 142 of the hybrid fin is about equal to the height 135 of the second fin 130, i.e. about 95% to about 100% of the height of the second fin. Other values and ranges are also within the scope of this disclosure.

As illustrated here, the horn 146 of the hybrid fin 140 extends upwards and is located between the n-type epitaxial feature 128 and the p-type epitaxial feature 138. In particular embodiments, the horn 146 extends upward to about one-half the height 139 of the p-type epitaxial feature 138. In particular embodiments, the horn extends upward for about 30% to about 50% of the height 139 of the p-type epitaxial feature 138.

Referring now to the X-axis cross-sectional view of FIG. 1C, additional parts of the semiconductor device are seen. Initially, the second fin 130 is shown along with two p-type epitaxial structures 138 on opposite ends of the second fin. Metal contacts 156 pass through the capping dielectric layer 154 down to each p-type epitaxial structure 138. Between the two p-type epitaxial structures 138, a gate oxide layer 160 contacts the second fin. A gate electrode 162 contacts the gate oxide layer 160. Another metal contact 164 passes through the capping dielectric layer 154 to the gate electrode 162. If desired, optional vertical dielectric gate spacers 166 may be located adjacent the gate electrode to further separate it from the two p-type epitaxial structures 138.

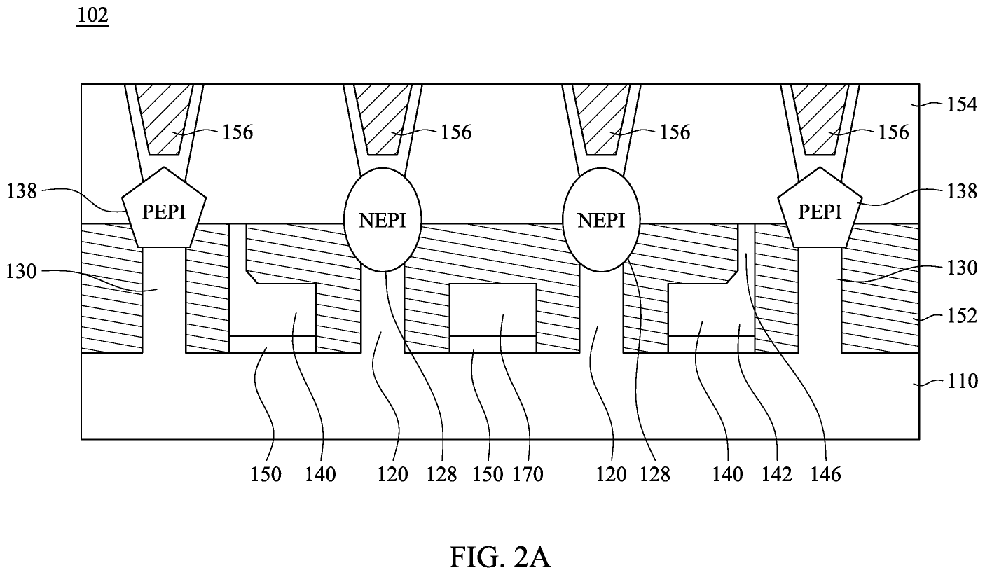

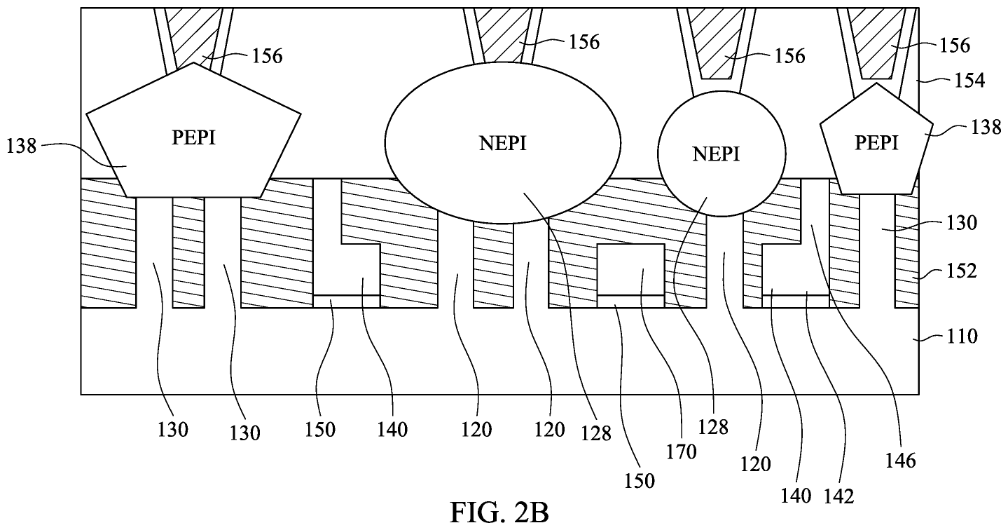

FIG. 2A is a side cross-sectional view showing a second example embodiment of a semiconductor device 102, in accordance with some embodiments. In this embodiment, there are two n-type epitaxial structures located between two p-type epitaxial structures.

In this embodiment, four fins are illustrated, two first fins 120 or central fins and two second fins 130 or outer fins. Each first fin 120 supports an n-type epitaxial structure 128, and each second fin 130 supports a p-type epitaxial structure 138. Three hybrid fins 140, 170 are present between each set of fins. Of note, the hybrid fin 170 located between the two n-type epitaxial structures 128 does not have a horn like the other two hybrid fins 140.

FIG. 2B is a side cross-sectional view showing a third example embodiment of a semiconductor device 102, in accordance with some embodiments. In this embodiment, on the left-hand side, a single p-type epitaxial structure 138 is supported by two adjacent second fins 130. Similarly, a single n-type epitaxial structure 128 is supported by two adjacent first fins 120. On the right-hand side, a single p-type epitaxial structure 138 is supported by one second fin 130, and a single n-type epitaxial structure 128 is supported by one first fin 120. Generally, any number of fins may be used to support an epitaxial structure as needed. A hybrid fin 140 having a horn and a base is located between each n-type epitaxial feature 128 and the p-type epitaxial feature 138.

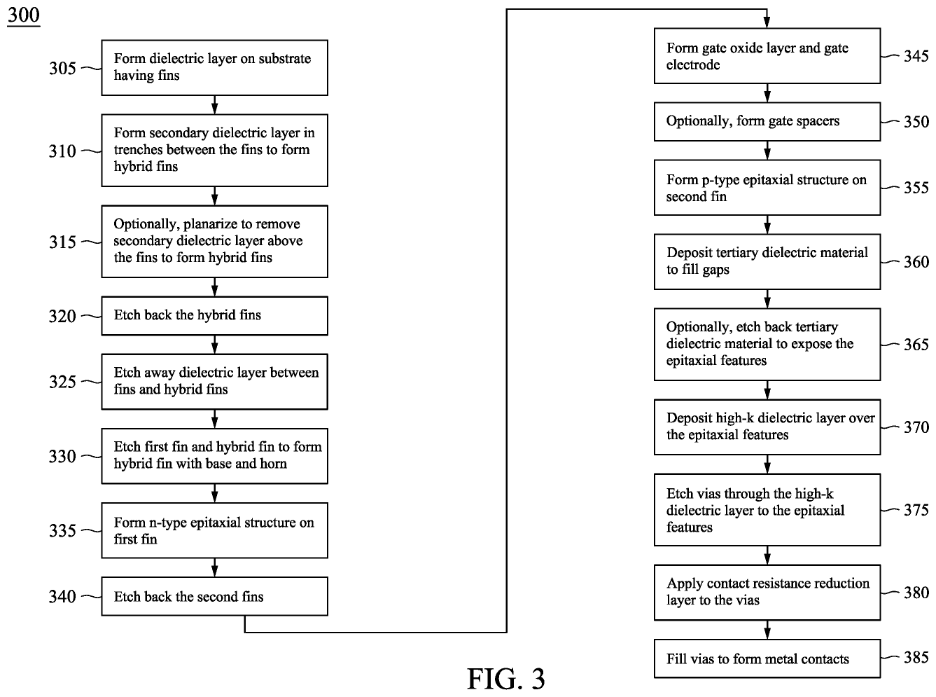

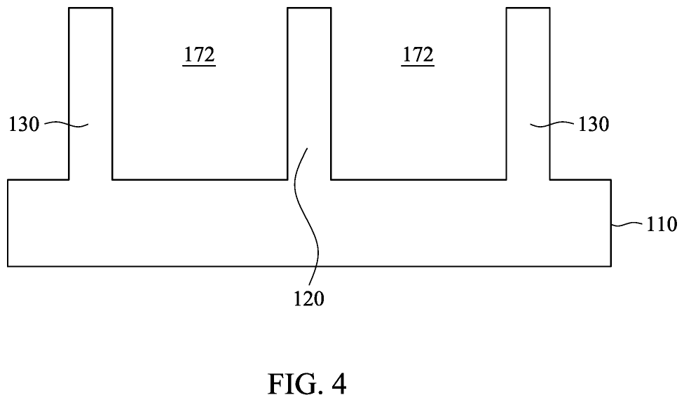

FIG. 3 is a flow chart illustrating a method 300 for making a semiconductor device, in accordance with some embodiments. Some steps of the method are also illustrated in FIGS. 4-16. These figures provide different views for better understanding. While the method steps may be discussed below in terms of single or multiple fins or structures, such discussion should also be broadly construed as applying to multiple or single fins or structures, respectively.

It is noted that certain conventional steps are not expressly described in the discussion below. For example, the pattern/structure formed in a given layer may be done by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Continuing, then, FIG. 4 illustrates a beginning state, before the method steps of FIG. 3. As illustrated here, a substrate 110 has a plurality of semiconducting fins formed thereon. The substrate and the fins are made of the same material. Following FIG. 1A, a first fin 120 and two second fins 130, also referred to as a central fin and two outer fins, are illustrated here. Trenches 172 are present between each pair of adjacent fins.

The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

The substrate is subsequently shaped to form the fins 120, 130. Typically, one or more hardmask layers is/are applied to the substrate. Mandrels are then formed upon the hardmask layer(s) over the substrate. This can be done by depositing a mandrel material layer, forming a photoresist layer upon the mandrel material layer, exposing the photoresist to radiation and developing the photoresist layer to form a mandrel pattern, and then etching the mandrel material layer to form the mandrels. If desired, the mandrels are then used as a mask, and etching is performed through the hardmask layer(s) and into the substrate is performed to form the fins. Alternatively, in a process known as self-aligned double patterning (SADP), spacers are formed on the sidewalls of the mandrels, and the mandrels are then removed. The spacers are then used as a mask, and etching is performed through the hardmask layer(s) and into the substrate is performed to form the fins. Self-aligned quadruple patterning (SAQP) is a similar process, and can also be used to form the fins.

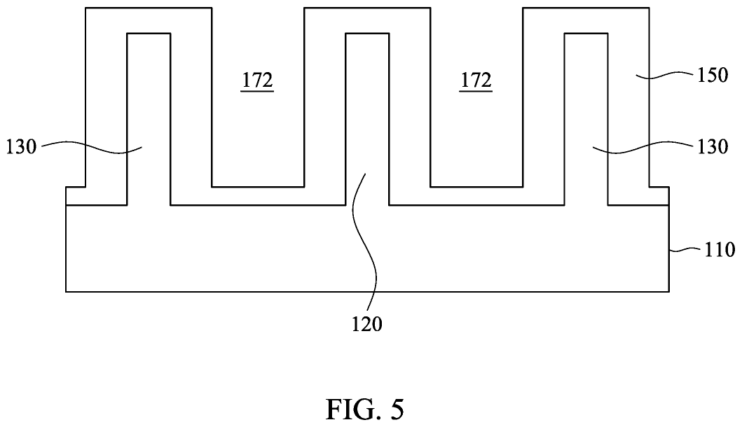

Next, in step 305 of FIG. 3 and as illustrated in FIG. 5, a dielectric layer 150 is formed upon the fins 120, 130 and the substrate 110. In typical embodiments, the dielectric layer is formed from silicon dioxide (SiO₂), which has a dielectric constant of 3.9. However, any suitable dielectric material may be used. The dielectric layer can be formed by thermal oxidation, physical vapor deposition (PVD), chemical vapor deposition (CVD), atomic layer deposition (ALD), oxidation, or other suitable deposition technique or growth technique. The dielectric layer conforms to the surface of the fins and the substrate, and the trenches 172 are still present between fins.

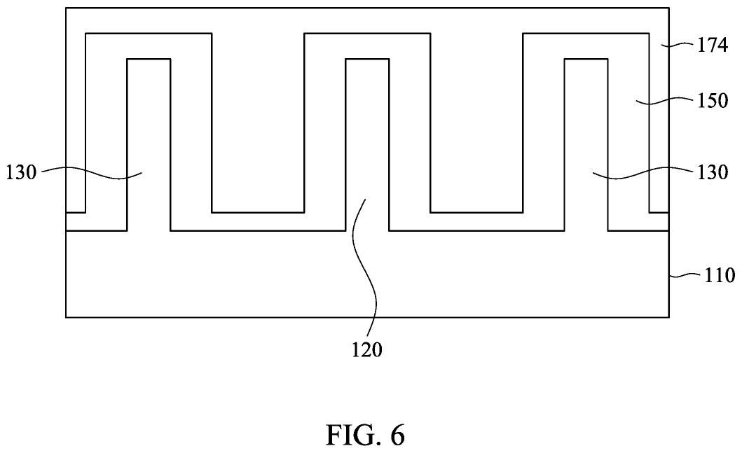

Then, in step 310 of FIG. 3 and as illustrated in FIG. 6, a secondary dielectric material is deposited into the trenches to form a secondary dielectric layer 174. The secondary dielectric material has a dielectric constant that is greater than the dielectric constant of the dielectric layer 150. In some particular embodiments, the secondary dielectric material has a dielectric constant that is greater than 3.9 (i.e. that of SiO₂). Examples of suitable materials may include silicon carbon nitride (SiCN, k=4 to 7.0), aluminum oxide (Al₂O₃, k=8-10), silicon nitride (SiN, k˜8-10), hafnium silicates (HfSiₓO_{y}, k˜11) or zirconium silicates (ZrSiₓO_{y}, k˜13). As illustrated here, the secondary dielectric material fills the trenches and forms a layer on top of the substrate and over the fins 120, 130. However, the formation of the layer over the fins is not required.

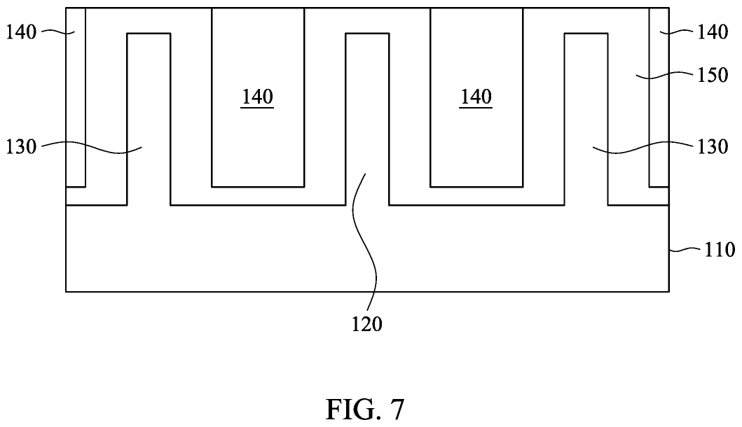

Next, in optional step 315 of FIG. 3 and as illustrated in FIG. 7, the substrate is planarized to remove the secondary dielectric layer from over the fins 120, 130. The planarizing may be performed, for example, using a chemical mechanical polishing (CMP) process. Hybrid fins 140 are thus formed from the secondary dielectric layer between the fins 120, 130.

Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate, removing undesired materials and creating a highly level surface on the wafer. A post-CMP cleaning step is then carried out using rotating scrubber brushes along with a washing fluid to clean one or both sides of the wafer substrate.

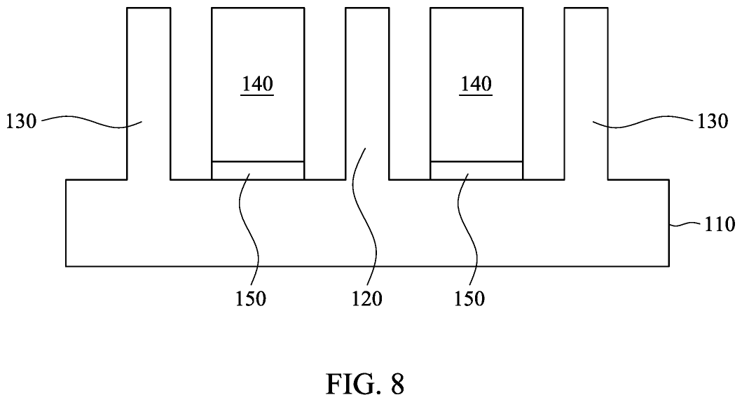

Then, in step 320 of FIG. 3, the hybrid fins 140 are etched back so that they are not higher than the fins 120, 130, or put another way the height of the hybrid fins is reduced. In step 325 of FIG. 3, the portions of the dielectric layer 150 between the hybrid fins 140 and the fins 120, 130 are etched away. The resulting structure is shown in FIG. 8. Each hybrid fin 140 sits upon a dielectric layer 150. In this view, a structure is formed upon a substrate that comprises a first fin 120, a second fin 130, and a hybrid fin 140 located between the first fin and the second fin.

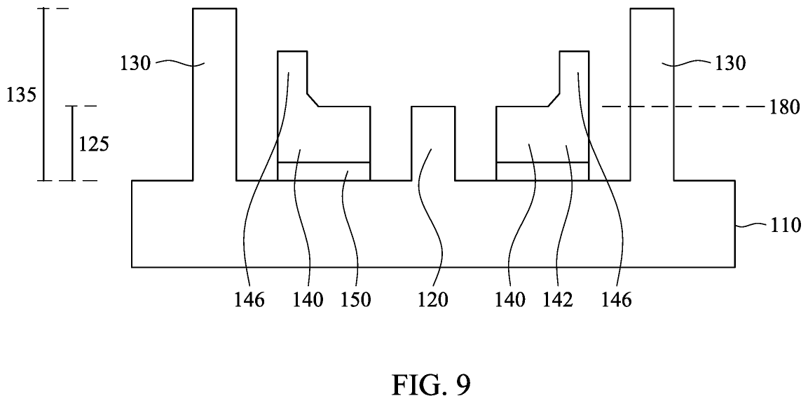

Next, in step 330 of FIG. 3, the first fin 120 and a hybrid fin 140 are etched to change the shape of the hybrid fin 140. The resulting structure is shown in FIG. 9. In this illustration, both hybrid fins 140 on each side of the first fin 120 are etched to create a recess in each hybrid fin. The hybrid fin 140 can now be described as having a base 142 and a horn 146. The horn 146 extends upward from the base 142 on the side of the base that is proximal to a second fin 140. After the etching, the first fin 120 and the base 142 extend to the same level (indicated with reference numeral 180). The height of the first fin is reduced compared to before this etching step. After this step, the height 135 of the second fins 130 is greater than the height 125 than the first fin 120.

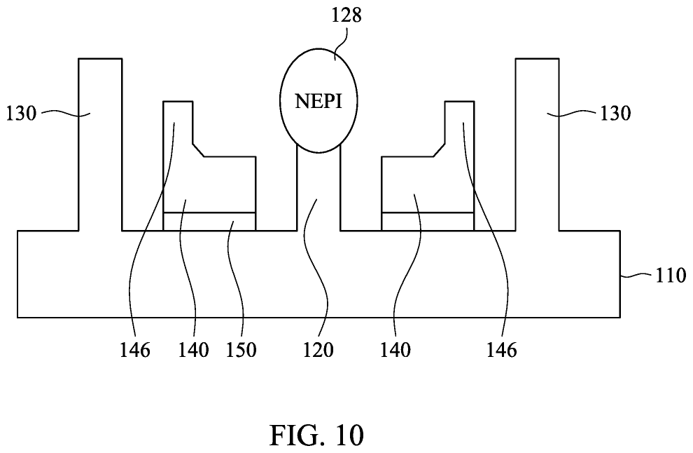

Next, in step 335 of FIG. 3 and as illustrated in FIG. 10, an n-type epitaxial structure 128 is formed on the first fin 120. This can be done by depositing multiple crystalline layers. The epitaxial structure may grow vertically and/or horizontally to form facets, which may correspond to crystalline planes of the material used for the substrate. Suitable epitaxial growth methods may include CVD, ALD, or molecular beam epitaxy (MBE). Suitable materials for the n-type epitaxial structure may include Si, SiP, SiC, or SiCP. As discussed with respect to FIG. 2B, this epitaxial structure can be formed upon any number of adjacent fins as desired.

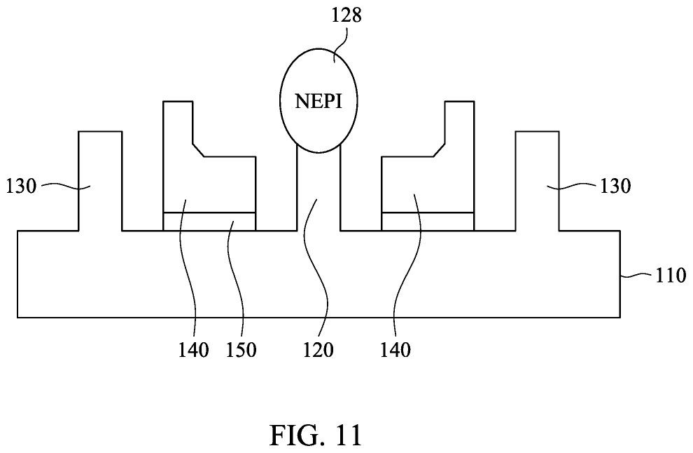

Next, in step 340 of FIG. 3 and as illustrated in FIG. 11, the second fins 130 are recessed by etching. They may be etched down to the same level or height to which the first fin 120 was etched (see FIG. 9), which is a level below that of the horns 146 of the hybrid fins 140.

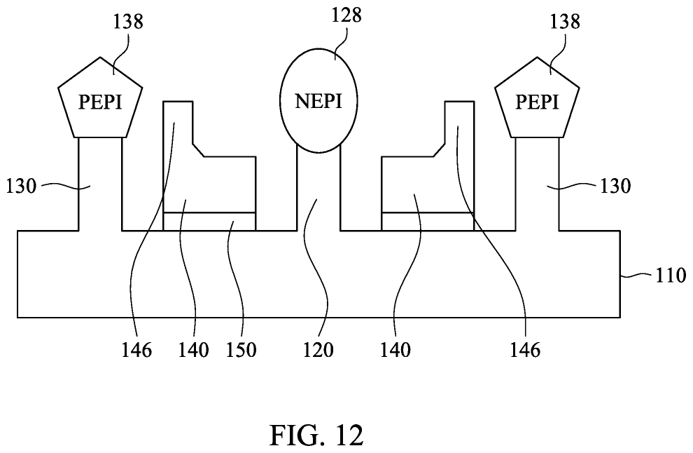

Then, in step 355 of FIG. 3 and as illustrated in FIG. 12, a p-type epitaxial structure 138 is formed on each second fin 130. This may be done in the same manner as previously described for the n-type epitaxial structure. Suitable materials for the p-type epitaxial structure may include Si, SiGe, or Ge, which may be doped with boron. Again, this epitaxial structure can be formed upon any number of adjacent fins as desired.

It is noted that one reason for shaping the hybrid fin to include a lower height on the side proximal the n-type epitaxial structure 128 is to permit the n-type epitaxial structure 128 to have a larger volume than the p-type epitaxial structure 138. This improves the electrical performance of the semiconductor device. The height 129 of the n-type epitaxial structure 128 and the height 139 of the p-type epitaxial structure 138 may independently be from about 15 nm to about 25 nm.

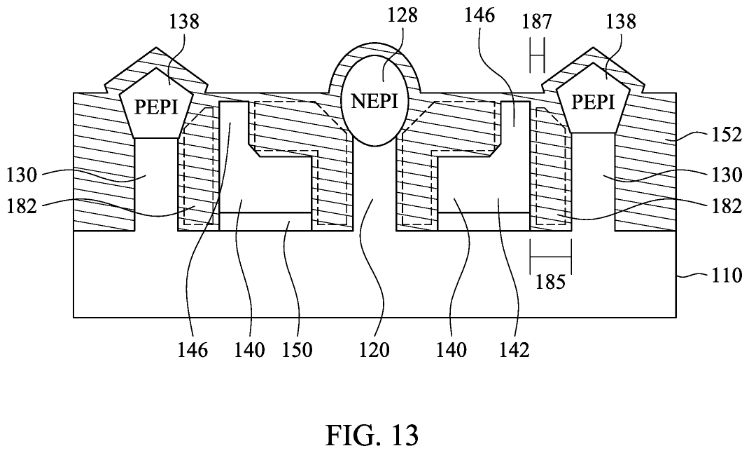

Next, in step 360 of FIG. 3 and as illustrated in FIG. 13, a tertiary dielectric material is deposited. The tertiary dielectric material desirably fills any gaps 182 (marked with dashed line) between the hybrid fin 140 and the second fin 130/p-type epitaxial feature 138, and thus may also be considered a gap fill layer or etch stop layer 152. As illustrated here, the tertiary dielectric material also fills the gaps 182 between the hybrid fin 140 and the first fin 120/n-type epitaxial feature 128, and also covers the base 142 of the hybrid fin 140, and also forms a thin layer upon the epitaxial features themselves, but this is not required. Suitable dielectric materials have been previously described. In particular embodiments, the tertiary dielectric material is a different material from the hybrid fin 140. In further particular embodiments, the tertiary dielectric material is silicon nitride (SIN). It is noted that a given second fin 130/p-type epitaxial feature 138 is considered to be proximal to a given hybrid fin 140 if there is no a first fin 120/n-type epitaxial feature 128 between it and the hybrid fin.

It should be noted that the width 185 between the hybrid fin base 142 and the second fin 130 is larger than the width 187 between the hybrid fin horn 146 and the p-type epitaxial structure 138. The width 187 depends on the height of the hybrid fin horn 146, and if the horn is too high, then it is difficult for the gap to be filled with the tertiary dielectric material. Controlling the height of the horn permits the gap to be completely filled.

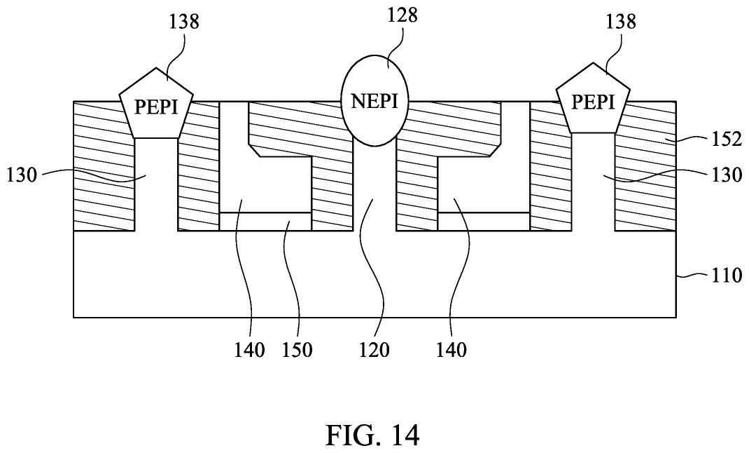

In optional step 365 of FIG. 3 and as illustrated in FIG. 14, the tertiary dielectric material is etched as needed to expose the n-type epitaxial feature 128 and the p-type epitaxial feature(s) 138.

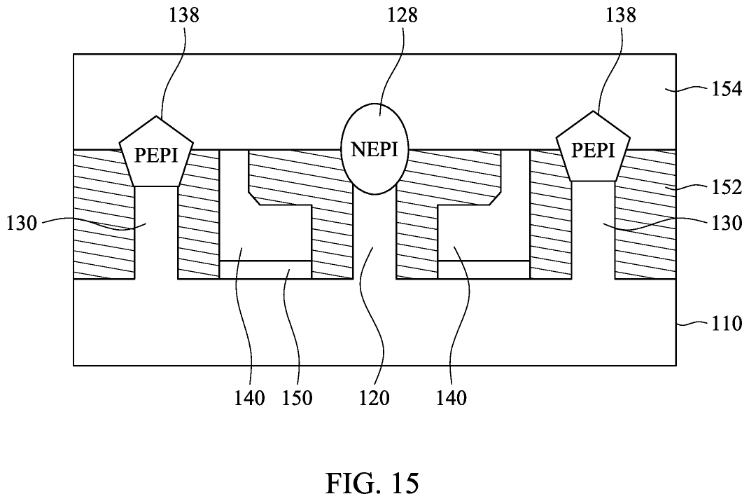

Then, in step 370 of FIG. 3 and as illustrated in FIG. 15, a capping dielectric layer 154 is deposited over the n-type epitaxial feature 128 and the p-type epitaxial feature(s) 138. The capping dielectric layer 154 is made of a suitable dielectric material. Besides those materials previously described, other high-k dielectric materials that could be used in this layer may include hafnium dioxide (HfO₂, k˜25), zirconium dioxide (ZrO₂, k=22-47 depending on crystal structure/amorphous), hafnium oxynitride (HfOₓN_{y}, k=14-21)) or zirconium oxynitride (ZrOₓN_{y}, k˜27).

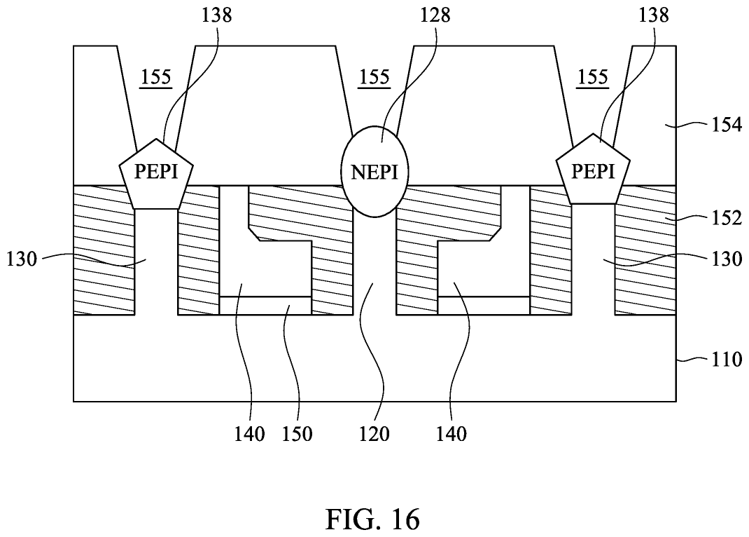

Then, in step 375 of FIG. 3, vias 155 are etched through the capping dielectric layer 154 to each n-type epitaxial feature 128 and p-type epitaxial feature 138. The resulting structure is shown in FIG. 16.

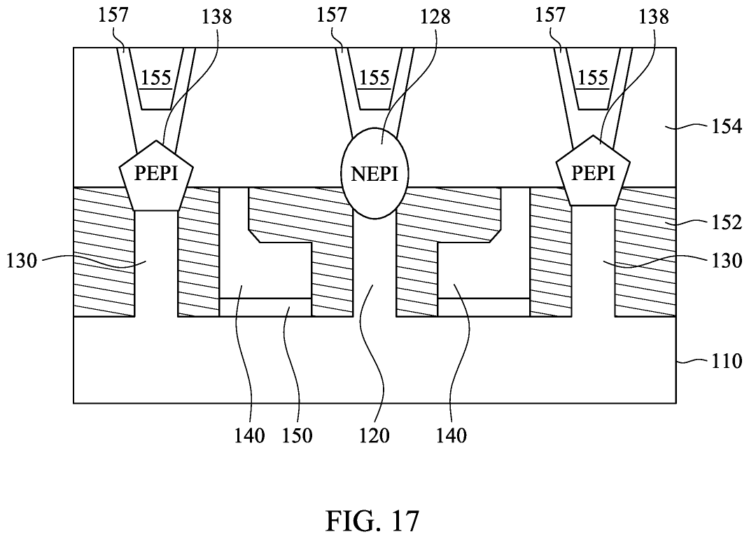

Next, in step 380 of FIG. 3, an electrical contact resistance reduction layer is applied to the vias. This contact resistance reduction layer reduces electrical contact resistance that can arise. Examples of suitable materials may include Ti, Co, In, Ga, or alloys thereof, although other materials are within the scope of the present disclosure. In particular embodiments, the electrical contact resistance reduction layer is formed from Ti, Co, or alloys thereof. This layer can be applied by ALD, sputtering, or other suitable processes. The resulting structure is shown in FIG. 17.

Finally, in step 385 of FIG. 3, the vias are filled with an electrically conductive material that forms a plug 158. The combination of contact resistance reduction layer 157 and plug 158 can be considered a metal contact 156. The contact resistance reduction layer 157 separates the epitaxial features 128, 138 from the plug 158. In particular embodiments, the plug 158 is formed from a metal such as aluminum (Al), tungsten (W), Cu, Au, Fe, Ru, Ir, Pt, Co, Rh, Pd, Ti, Ta, or alloys thereof, although other materials are within the scope of the present disclosure. In particular embodiments, the plug is formed from tungsten (W). The plug can be formed by PVD or CVD, or other processes such as sputtering. The resulting structure is shown in FIG. 1.

The second example embodiment of FIG. 2 is made in a substantially similar manner as described in FIG. 3 and FIGS. 4-16. The main difference is that two adjacent fins are designated as first fins or central fins 120, upon which n-type epitaxial features 128 will be formed. In addition, in the etching step 330 in which the horns 146 are formed, due to its location in the central area and not on the edges of the etch, the hybrid fin 170 located between the two n-type epitaxial structures 128 does not have a horn, and is essentially only reduced in height.

The discussion above and the illustrations of FIGS. 4-16 relate to the formation of the n-type epitaxial features 128 and the p-type epitaxial features 138, but do not discuss the formation of the other features of the semiconductor device illustrated in the X-axis view of FIG. 1C.

Referring now to FIG. 1C and to FIG. 3, the gate oxide layer 160 and the gate electrode 162 are usually deposited after the second fins 130 have been recessed in step 340, and prior to the gap filling in step 360. Their deposition and formation are indicated in step 345 of FIG. 3.

The gate oxide layer may be any dielectric material, for example silicon dioxide, hafnium silicate, zirconium silicate, hafnium dioxide, or zirconium dioxide. The gate oxide layer may be formed by thermal oxidation, for example at a temperature of about 850° C. to about 950° C. in the presence of water or oxygen (O₂). As yet another example, the gate oxide layer could be formed by a chemical vapor deposition (CVD) process, for example using O₂ along with silane (SiH₄) or dichlorosilane (SiH₂Cl₂), or using tetraethyl orthosilicate (TEOS) at elevated temperatures above about 600° C. As yet another example, the gate oxide layer could be formed by the decomposition of TEOS at temperatures of about 600° C. to about 650° C., or through plasma enhanced CVD at lower temperatures.

The gate electrode may be any electrically conductive material as previously described. The gate electrode may be any electrically conductive material, for example aluminum, polysilicon (doped or undoped), tungsten, a metal silicide such as TiSi or MoSi₂ or TaSi or WSi₂, or electrically conductive metals or alloys such as TiN, Pt, Co, Rh, Pd, Ti, Ta, TaN, Nb, WN, or WN/RuO₂. The gate electrode can be formed by PVD or CVD, or other processes such as sputtering.

In optional step 350, gate spacers 166 are formed adjacent the gate electrode 162. The gate spacers act as an electrical insulator, and can be made from any suitable dielectric material, such as silicon dioxide (which may be doped with fluorine or carbon). The gate spacer can be formed by a deposition process (e.g. PVD or CVD) on the entire surface, then applying a patterned mask and etching to remove material from undesired locations.

The via/metal contact 164 leading to the gate electrode 162 may also be formed during steps 375 and 380, along with the vias/metal contacts 156 for the n-type epitaxial features 128 and the p-type epitaxial features 138.

The resulting semiconductor device can be used in several applications. For example, it may be useful as an inverter, which is used in applications such as a ring oscillator and static random access memory (SRAM). A ring oscillator is composed of an odd number of inverters in a ring, whose output oscillates between two voltage levels. The inverters are joined to each other in series and the output of the last inverter is fed back into the first inverter. A ring oscillator can be used to generate a voltage or current signal with a specific frequency, which is useful for synchronizing computation processes in digital systems; or can be used as part of a hardware random number generator; or to measure the effect of voltage and temperature on a chip. In SRAM, a pair of cross-coupled inverters are used to store one bit.

The methods of the present disclosure and the resulting structures have several advantages. First, because the hybrid fin is shaped to have a horn upon a base of reduced height, additional space is created so the volume of the n-type epitaxial structure can be increased. At the same time, the insulating properties of the hybrid fin are maintained. This improves electrical performance and reduces capacitance. In addition, the via/metal contact ideally contacts only the n-type epitaxial structure or the p-type epitaxial structure. However, at the smaller dimensions now being used to form integrated circuits, the critical dimension (CD) may be such that the via/metal contact is shifted to one side of the epitaxial structure. It is undesirable for the metal material to be deposited between the hybrid fin and an epitaxial structure. The reduced height of the hybrid fin permits the gap fill/etch stop material to more easily fill in the volume between the hybrid fin and the epitaxial structure so that metal material cannot enter that volume. This reduces or eliminates leakage paths that could otherwise be formed when undesired shift of the metal contact occurs.

Some aspects of the present disclosure thus relate to methods for making a semiconductor device. A structure comprising a first fin, a second fin, and a hybrid fin located between the first fin and the second fin is formed upon a substrate. The first fin and the hybrid fin are then etched, such that the hybrid fin includes a base and a horn extending from the base on a side proximal to the second fin.

Also disclosed herein in various embodiments are semiconductor devices that comprise a substrate, at least one first fin, at least one second fin, and a hybrid fin. The at least one first fin is on the substrate and supports an n-type epitaxial feature. The at least one second fin is also on the substrate and supports a p-type epitaxial feature. The hybrid fin is located on the substrate between the at least one first fin and the at least one second fin. The hybrid fin includes a base and a horn extending upwards from the base on a side proximal to the at least one second fin.

Also disclosed herein are methods for making a semiconductor device. A structure is formed upon a substrate that comprises at least one central fin located between two hybrid fins and two outer fins located on opposite sides of the two hybrid fins from the at least one central fin. The at least one central fin and the two hybrid fins are then etched, such that each hybrid fin includes a base and a horn extending from the base on a side proximal to an outer fin. An n-type epitaxial feature is formed on the at least one central fin. A p-type epitaxial feature is formed on each of the two outer fins. A gap fill material is deposited to fill gaps between each hybrid fin and the second fin proximate each hybrid fin. Metal contacts are then formed to the n-type epitaxial feature(s) and the p-type epitaxial features. In particular embodiments, there are two central fins.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a semiconductor device, comprising:
forming a structure upon a substrate comprising a first fin, a second fin, and a hybrid fin located between the first fin and the second fin; and
etching the hybrid fin, such that the hybrid fin includes a base and a horn extending from the base on a side proximal to the second fin.

2. The method of claim 1, wherein the horn of the hybrid fin has a height of about 5 to about 10 nanometers.

3. The method of claim 1, wherein the base of the hybrid fin has a height of about 20 to about 30 nanometers.

4. The method of claim 1, wherein the horn of the hybrid fin has a width of about 3 to about 8 nanometers.

5. The method of claim 1, wherein the base of the hybrid fin has a width of about 10 to about 20 nanometers.

6. The method of claim 1, wherein a height of the second fin is about equal to a height of the base of the hybrid fin.

7. The method of claim 1, wherein the first fin is concurrently etched with the hybrid fin.

8. The method of claim 1, wherein the first fin and the second fin are formed from the substrate; and the hybrid fin is formed from a dielectric material with a dielectric constant greater than 3.9.

9. The method of claim 1, further comprising:
forming an n-type epitaxial feature on the first fin;
forming a p-type epitaxial feature on the second fin; and
depositing a gap fill material to fill gaps between the hybrid fin and the second fin.

10. The method of claim 9, wherein the horn of the hybrid fin extends at most to about half the height of the p-type epitaxial feature.

11. The method of claim 9, wherein a ratio of a height of the p-type epitaxial feature to a height of the horn of the hybrid fin is about 2:1 to about 3:1.

12. The method of claim 9, wherein a volume of the n-type epitaxial feature is greater than a volume of the p-type epitaxial feature.

13. The method of claim 9, further comprising:
depositing a capping dielectric layer over the n-type epitaxial feature and the p-type epitaxial feature; and
forming metal contacts to the n-type epitaxial feature and the p-type epitaxial feature that pass through the capping dielectric layer.

14. The method of claim 13, wherein each metal contact comprises an electrical contact resistance reduction layer and a metal plug.

15. A semiconductor device, comprising:
at least one first fin on a substrate that supports an n-type epitaxial feature;
at least one second fin on the substrate that supports a p-type epitaxial feature; and
a hybrid fin located between the at least one first fin and the at least one second fin, the hybrid fin including a base and a horn extending upwards from the base on a side proximal to the at least one second fin.

16. The semiconductor device of claim 15, further comprising a gap fill material between the hybrid fin and the at least one second fin.

17. The semiconductor device of claim 15, further comprising:
a capping dielectric layer over the n-type epitaxial feature and the p-type epitaxial feature; and
metal contacts to the n-type epitaxial feature and the p-type epitaxial feature passing through the capping dielectric layer.

18. The semiconductor device of claim 15, wherein the horn of the hybrid fin extends at most to about half the height of the p-type epitaxial feature.

19. A method for making a semiconductor device, comprising:
forming a structure upon a substrate comprising at least one central fin located between two hybrid fins and two outer fins located on opposite sides of the two hybrid fins from the at least one central fin;
etching the at least one central fin and the two hybrid fins, such that each hybrid fin includes a base and a horn extending from the base on a side proximal to an outer fin;
forming an n-type epitaxial feature on the at least one central fin;
forming a p-type epitaxial feature on each of the two outer fins;
depositing a gap fill material to fill gaps between each hybrid fin and the second fin proximate each hybrid fin; and
forming metal contacts to the n-type epitaxial features and the p-type epitaxial features.

20. The method of claim 19, wherein the structure has two central fins.
